(19) United States
(12) Patent Application Publication
(10) Pub. No.: US 2026/0101723 A1
(43) Pub. Date: Apr. 9, 2026

(54) INTERACTIVE USER INTERFACE FOR SUBSTRATE EDGE PROFILE

(71) Applicant: APPLIED MATERIALS, INC., Santa Clara, CA (US)

(72) Inventors: Chen Chen, Santa Clara, CA (US); Michael Koltonski, Santa Clara, CA (US); Zhaozhao Zhu, Santa Clara, CA (US)

(21) Appl. No.: 18/909,329

(22) Filed: Oct. 8, 2024

(51) Int. Cl. H01L 21/66; G05B 19/418; H01L 21/67

(52) U.S. Cl. CPC H10P 74/23; G05B 19/4188; H10P 72/0604; G05B 2219/45031

(57) ABSTRACT

A method for calibrating an edge ring height is described herein. The method includes measuring first thicknesses at a plurality of locations of a substrate using a substrate measurement system of a substrate processing system, and performing a process on the substrate in a process chamber including an edge ring that surrounds the substrate. The method also includes measuring second thicknesses the plurality of locations and estimating a rate and edge ring height of the edge ring and calibrating the edge ring height based on the estimated edge ring height.

### TECHNICAL FIELD

Some embodiments of the disclosure relate, in general, to substrate edge profile, and in particular, to interactive user interface for substrate edge profile based on a processing or treatment rate such as an etch rate or deposition rate.

### BACKGROUND

Processing of a substrate at a manufacturing system generally includes multiple processing operations that are performed for the substrate in accordance with a pre-determined process recipe. In some instances, one or more conditions at the manufacturing system can change unexpectedly during the processing of the substrate. If the substrate is processed according to the pre-determined process recipe as the change in manufacturing conditions occur, errors can result during the process and a finished substrate can be defective. In some instances, an operation of the process recipe can be modified in view of the changed condition in order to prevent the error from occurring during the processing of the substrate. However, it can be difficult for an operator of the manufacturing system to identify which operation of the process recipe should be modified.

### SUMMARY

In an embodiment of the present disclosure, a method is provided to calibrate the edge ring height of a process chamber. The method may include measuring first thicknesses at a plurality of locations of a substrate using a substrate measurement system. The method may further include performing an etch process, a deposition process, or treatment process on the substrate in a process chamber including an edge ring that surrounds the substrate. The method may also include measuring second thicknesses at the plurality of locations of the substrate using the substrate measurement system. The method may include estimating an etch rate, deposition rate, or treatment rate at an edge of the substrate based on the first thicknesses and the second thicknesses, and estimating an edge ring height of the edge ring based on the etch rate, deposition rate, or treatment rate profile. The method may also include calibrating the edge ring height based on the estimated edge ring height by determining a difference between the estimated edge ring height and a target edge ring height, which is determined by a target etch rate profile, target deposition rate profile, or target treatment rate profile and adjusting the height of the edge ring based on the determined difference.

In another embodiment, a method for determining a mathematical model is provided. The method may include receiving data, such as data from a design of experiments (DOE), wherein the data may include a plurality of data entries, each data entry of the plurality of data entries including a pre-etch thickness profile of a substrate, a post-etch thickness profile of the substrate, and an edge ring height associated with an etch process performed on the substrate. In some embodiments, each data entry may include a pre-deposition or pre-treatment thickness profile of a substrate, a post-deposition or post-treatment thickness profile, or an edge ring height associate with a deposition process or treatment process performed on the substrate. The method may also include processing the plurality of data entries to determine, for each data entry of the plurality of data entries, a normalized etch rate, normalized deposition rate or normalized treatment rate at an edge of the substrate. The method may include determining a mathematical model that relates edge ring height to the normalized etch rate, normalized deposition rate, or normalized treatment rate at the edge of the substrate based on the data from the DOE, wherein the mathematical model is usable to calibrate the edge ring height for one or more process chambers.

In yet another embodiment, a system is provided. The system includes a process chamber that is configured to perform a semiconductor process (e.g., etch process). The system may further include one or more robots that is configured to move the substrate from the process chamber to a substrate measurement system. The system may include a substrate measurement system configured to measure a spectra map of the substrate and to generate a thickness map of the substrate. The system may include a computing device to process data from the spectra map using a mathematical model, wherein the mathematical model outputs an estimated thickness and etch rate for the substrate.

### BRIEF DESCRIPTION OF THE DRAWINGS

The disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a top schematic view of an example processing system, according to one embodiment.

FIG. 2 is a cross-sectional schematic side view of a processing chamber, according to aspects of the present disclosure.

FIGS. 3A-3C represents a variety of different edge heights and plasma sheath shapes according to different aspects of the present disclosure.

FIG. 4 is a flowchart of method of calibrating the edge ring height according to an embodiment.

FIG. 5 is an illustration of a user interface dashboard according to an embodiment.

FIG. 6 is a flowchart of a method of determining a mathematical model according to an embodiment.

FIG. 7 depicts a block diagram of an example computing device capable of process drift and film thickness determination, operating in accordance with one or more aspects of the disclosure.

### DETAILED DESCRIPTION

Embodiments described herein provide an integrated substrate measurement system to improve manufacturing process performance. It has been found that when processing a substrate (e.g., a wafer), the processing conditions such as etch rate, etch directionality and/or deposition or treatment rate are sensitive to ring height of an edge ring. For example, when a substrate is processed during an etch process, features of the substrate may be tilted (e.g., the angle of etched trenches, holes, and/or other features may not be 90 degrees to a plane of the substrate). In some embodiments, sheath bending may occur in a plasma sheath around a substrate during plasma processing (e.g., plasma etching, plasma deposition, plasma treatment, etc.), affecting the angle at which the treatment (e.g., etching) may occur and/or the etch rate or deposition rate or treatment rate at an edge of the substrate. By adjusting the edge ring height, then the processing conditions may be more effectively controlled.

Embodiments provide techniques for determining an optimal height for an edge ring to achieve a target etch rate, deposition rate or treatment rate at a substrate edge and/or to achieve a target feature tilt at the substrate edge. In embodiments, a correlation may be established between edge ring height and substrate edge etch rate, deposition or treatment rate and/or feature tilt (e.g., based on a design of experiments (DOE)). Once the correlation is established for a process chamber and/or process recipe, a test substrate may be processed using the process chamber with the edge ring at a set height. The test substrate may be measured for thickness (e.g., using one or more optical measurements) before and after being processed by the process chamber. The before and after thicknesses may be used to determine etch rate at various locations on the substrate (e.g., at an edge of the substrate). Based on the determined etch rate, deposition rate, or treatment rate at the edge of the substrate and the determined correlation between edge ring height and substrate edge etch rate, a current edge ring height used to process the test substrate may be determined. The edge ring height may then be calibrated based on a difference between the determined edge ring height and an edge ring height that is associated with a target substrate edge etch rate, deposition rate or treatment rate.

Various components of the integrated substrate measurement system can be operatively coupled to a system controller configured to control a process for a substrate at a manufacturing system. The system controller may be configured to receive data from various portions of a manufacturing system and to store data at a data store dedicated to store data collected at the integrated substrate measurement system. The system controller may receive data from one or more portions of the manufacturing system (e.g., a processing chamber, a load lock, etc.) before, during, or after processing of a substrate. The processing of a substrate may include performing an etch process, treatment process, or a deposition process.

The substrate measurement system may be configured to measure a thickness of a substrate and to generate a profile map of the substrate. The substrate measurement system can generate the data for the substrate in response to a request to obtain the thickness of the substrate at a plurality of locations before or after the substrate is processed at the manufacturing system. The substrate measurement system may include one or more components that facilitate the generation of data for the substrate. For example, the substrate measurement subsystem can include a spectra sensing component for sensing spectra or spectrum from a portion of the substrate and generating spectral data for the substrate. In some embodiments, the spectra sensing component can be an interchangeable component that can be configurable based on a type of process performed at the manufacturing system or a target type of measurements to be obtained at the substrate measurement subsystem. For example, one or more components of the spectra sensing component can be interchanged at the substrate measurement subsystem to enable the collection of reflectometry spectral data, ellipsometry spectral data, hyperspectral imaging data, chemical imaging (e.g., x-ray photoelectron spectroscopy (XPS), energy-dispersive x-ray spectroscopy (EDX), (x-ray fluorescence (XRF), etc.) data, and so forth. The substrate measurement system may also include positional components configured to modify a position and/or orientation of the substrate within the substrate measurement subsystem. The positional components may also generate positional data associated with the substrate. The substrate measurement system may correlate positional data and spectral data generated for a portion of the substrate. The substrate measurement system may transmit the generated data (e.g., spectral data, positional data, etc.), to the system controller of the manufacturing system.

In embodiments, the system controller receives a profile map (e.g., of a thickness profile of a processed substrate), and processes the profile map to determine an etch rate at various locations on the substrate (e.g., in a center of the substrate and at an extreme edge of the substrate). In some embodiments, the system controller may process the profile map to determine a deposition rate or treatment rate at various locations on the substrate. The system controller may estimate a height of an edge ring (also referred to as a process kit ring) that was used during processing of the substrate based on the determined etch rate(s) or determined deposition or treatment rate(s). The system controller may compare the estimated edge ring height to a target edge ring height and may determine whether to modify the edge ring height based on a result of the comparison. The system controller may determine a normalized etch rate or deposition rate or treatment rate at the extreme edge of the substrate based on dividing the etch rate, deposition rate or treatment rate at the extreme edge by the etch rate, treatment rate, or deposition rate at one or more other locations of the substrate in some embodiments, and may optionally use the normalized etch rate, deposition rate or treatment rate to estimate the edge ring height. In some embodiments, the edge ring height may be calibrated based on the estimated edge ring height by determining a difference between the estimated edge ring height and a target edge ring height and adjusting the edge ring height of the edge ring based on the determined difference. Responsive to identifying the difference in edge ring height, the system controller may transmit a notification to a user of the manufacturing system recommending that the edge ring height be adjusted. In some embodiments, the system controller may automatically adjust the edge ring height without input from the user.

In some embodiments, the system controller may receive data from a design of experiments (DOE). The data may include a plurality of data entries, each data entry of the plurality of data entries including a pre-etch thickness profile (or pre-deposition thickness profile or pre-treatment thickness profile) of a substrate, a post-etch thickness profile (or post-deposition thickness profile or post-treatment thickness profile) of the substrate, and an edge ring height associated with an etch process, deposition process or treatment process performed on the substrate. In some embodiments, the system controller may process the plurality of data entries to determine, for each data entry of the plurality of the data entries, a normalized etch rate, deposition rate or treatment rate at an edge of the substrate. In some embodiments, the system controller may determine a mathematical model that relates edge ring height to the normalized etch rate, deposition rate or treatment rate at the edge of the substrate based on the data from the DOE. The mathematical model may be usable to calibrate the edge ring height for one or more process chambers.

The present disclosure provides methods to determine whether to adjust the edge ring height and/or to find a normalized etch rate, deposition rate or treatment rate to be used during processing. By generating measurements of the thicknesses at a plurality of locations of the substrate before, during, and/or after the substrate is processed at the manufacturing system, a system controller can determine if any changes have occurred within the manufacturing system that may affect the process for the substrate.

In some embodiments, a method is provided to calibrate the edge ring height using the substate measuring system of the present disclosure. The method includes measuring first thicknesses at a plurality of locations of a substrate using a substrate measurement system of a substrate processing system. In some embodiments, the method may include performing an etch process, a deposition process, or a treatment process on the substrate in a process chamber including an edge ring that surrounds the substrate. The etch process may be a plasma etch process. The deposition process may be a plasma deposition process such as plasma vapor deposition process. In some embodiments, the method may include measuring second thicknesses the plurality of locations of the substrate using the substrate measurement system. The method may further include estimating an etch rate, deposition rate, or treatment rate at an edge of the substrate based on the first thicknesses and the second thicknesses, estimating an edge ring height of the edge ring based on the etch rate, deposition rate, or treatment rate and calibrating the edge ring height based on the estimated edge ring height. The calibration may include determining a difference between the estimated edge ring height and a target edge ring height and adjusting the edge ring height of the edge ring based on the determined difference.

In some embodiments, the method may further include generating a first profile map of the substrate based on the first thicknesses and generating a second profile map of the substrate based on the second thicknesses. The first profile map and the second profile map may be used to estimate the etch rate, deposition rate, or treatment rate at the edge of the substrate. In some embodiments, estimating the etch rate, deposition rate, or treatment rate at the edge of the substrate may include determining a first etch rate, deposition rate, or treatment rate associated with a central location on the substrate based on the first thicknesses and the second thicknesses at the central location and determining a second etch rate, deposition rate, or treatment rate associated with the edge of the substrate based on the first and second thicknesses at the edge of the substrate. In some embodiments, a ratio may be determined between the second etch rate, deposition rate, or treatment rate and the first etch rate, deposition rate or treatment rate.

In some embodiments, the substrate may include a wafer having a notch. In some embodiments, the method may include determining the first thicknesses and the second thicknesses associated with the notch and removing the first thicknesses and the second thicknesses associated with the notch.

In some embodiments, the method may further include determining the etch rate, deposition rate, or treatment rate at a plurality of different radiuses of the substrate based on the first thicknesses and the second thicknesses and determining normalized rates at the plurality of different radiuses based on dividing the etch rates, deposition rates, or treatment rates at the plurality of different radiuses by one or more etch rates, deposition rates or treatment rates associated with a center of the substrate.

In some embodiments, the method may further include displaying the normalized rates at the plurality of different radiuses in a graphical user interface. The normalized rates may include a normalized etch rate, a normalized deposition rate, or a normalized treatment rate.

In some embodiments, the target edge ring height may be associated with a target tilt of etched features, and wherein calibrating the edge ring height causes substrates processed by the process chamber to have the target tilt of the etched features.

In another embodiment, a method for determining a mathematical model relating to edge ring height and normalized etch rate, normalized deposition rate or normalized treatment rate is provided. The method may include receiving data from a design of experiments (DOE), wherein the data may include a plurality of data entries. Each data entry of the plurality of data entries may include a pre-process thickness profile of a substrate, a post-process thickness profile of the substrate, and an edge ring height associated with an etch process, deposition process, or treatment process performed on the substrate. The method may further include processing the plurality of data entries to determine, for each data entry of the plurality of data entries, a normalized etch rate, deposition rate or treatment rate at an edge of the substrate. The method may also include determining a mathematical model that relates edge ring height to the normalized etch rate, deposition rate or treatment rate at the edge of the substrate based on the data from the DOE, wherein the mathematical model is usable to calibrate the edge ring height for one or more process chambers.

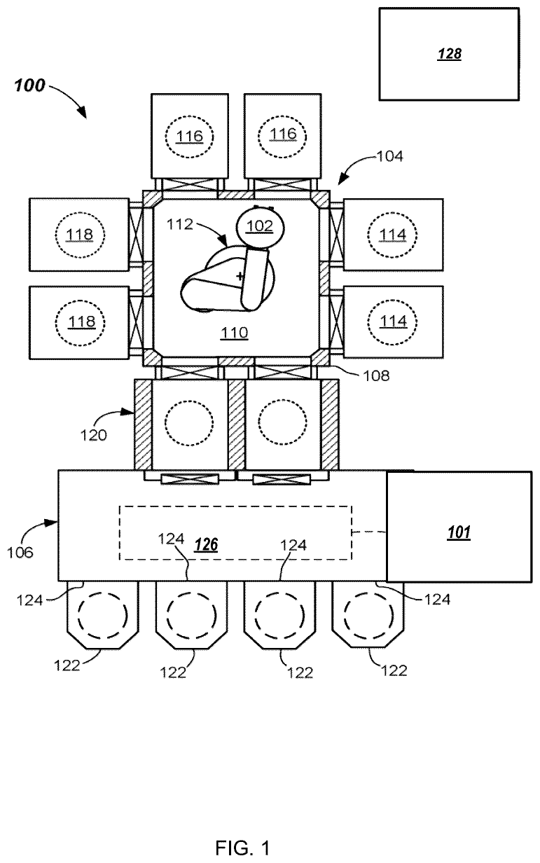

For ease with referring to the Figures, the Figures will be described in reference to performing an etch process. However, it is understood that the present methods and systems may also be applied to performing a deposition process or a treatment process. FIG. 1 is a top schematic view of an example processing system 100, according to one embodiment. In some embodiments, processing system 100 may be an electronics processing system configured to perform one or more processes on a substrate 102. In some embodiments, processing system 100 may be an electronics device manufacturing system. Substrate 102 can be any suitably rigid, fixed-dimension, planar article, such as, e.g., a silicon-containing disc or wafer, a patterned wafer, a glass plate, or the like, suitable for fabricating electronic devices or circuit components thereon.

Processing system 100 includes a process tool 104 (e.g., a mainframe) and a factory interface 106 coupled to process tool 104. Process tool 104 includes a housing 108 having a transfer chamber 110 therein. Transfer chamber 110 includes one or more processing chambers (also referred to as process chambers) 114, 116, 118 disposed therearound and coupled thereto. Processing chambers 114, 116, 118 can be coupled to transfer chamber 110 through respective ports, such as slit valves or the like.

Processing chambers 114, 116, 118 can be adapted to carry out any number of processes on substrates 102. A same or different substrate process can take place in each processing chamber 114, 116, 118. Examples of substrate processes include atomic layer deposition (ALD), physical vapor deposition (PVD), chemical vapor deposition (CVD), etching, annealing, curing, pre-cleaning, metal or metal oxide removal, or the like. In one example, a PVD process is performed in one or both of process chambers 114, an etching process is performed in one or both of process chambers 116, and an annealing process is performed in one or both of process chambers 118. Other processes can be carried out on substrates therein. Processing chambers 114, 116, 118 can each include a substrate support assembly. The substrate support assembly can be configured to hold a substrate in place while a substrate process is performed.

Transfer chamber 110 also includes a transfer chamber robot 112. Transfer chamber robot 112 can include one or multiple arms, where each arm includes one or more end effectors at the end of the arm. The end effector can be configured to handle particular objects, such as wafers. In some embodiments, transfer chamber robot 112 is a selective compliance assembly robot arm (SCARA) robot, such as a 2 link SCARA robot, a 3 link SCARA robot, a 4 link SCARA robot, and so on.

A load lock 120 can also be coupled to housing 108 and transfer chamber 110. Load lock 120 can be configured to interface with, and be coupled to, transfer chamber 110 on one side and factory interface 106 on another side. Load lock 120 can have an environmentally-controlled atmosphere that is changed from a vacuum environment (where substrates are transferred to and from transfer chamber 110) to at or near an atmospheric-pressure inert-gas environment (where substrates are transferred to and from factory interface 106) in some embodiments. In some embodiments, load lock 120 is a stacked load lock having a pair of upper interior chambers and a pair of lower interior chambers that are located at different vertical levels (e.g., one above another). In some embodiments, the pair of upper interior chambers are configured to receive processed substrates from transfer chamber 110 for removal from process tool 104, while the pair of lower interior chambers are configured to receive substrates from factory interface 106 for processing in process tool 104. In some embodiments, load lock 120 are configured to perform a substrate process (e.g., an etch or a pre-clean) on one or more substrates 102 received therein.

Factory interface 106 can be any suitable enclosure, such as, e.g., an Equipment Front End Module (EFEM). Factory interface 106 can be configured to receive substrates 102 from substrate carriers 122 (e.g., Front Opening Unified Pods (FOUPs)) docked at various load ports 124 of factory interface 106. A factory interface robot 126 (shown dotted) can be configured to transfer substrates 102 between substrate carriers 122 (also referred to as containers) and load lock 120. In other and/or similar embodiments, factory interface 106 is configured to receive replacement parts (e.g., such as edge rings) from replacement parts storage containers 123. Factory interface robot 126 can include one or more robot arms and can be or include a SCARA robot. In some embodiments, factory interface robot 126 has more links and/or more degrees of freedom than transfer chamber robot 112. Factory interface robot 126 can include an end effector on an end of each robot arm. The end effector can be configured to pick up and handle specific objects, such as wafers. Alternatively, or additionally, the end effector can be configured to handle objects such as process kit rings.

Any conventional robot type can be used for factory interface robot 126. Transfers can be carried out in any order or direction. Factory interface 106 can be maintained in, e.g., a slightly positive-pressure nonreactive gas environment (using, e.g., nitrogen as the nonreactive gas) in some embodiments.

Processing system 100 can include an integrated measurement and/or imaging system 101, which may be, for example, an integrated reflectometry (IR) system. Reflectometry is a measurement technique that uses measured changes in light reflected from an object to determine geometric and/or material properties of the object. Reflectance spectrometers measure the intensity of reflected light across a range of wavelengths. For dielectric films these intensity variations may be used to determine the thickness of the film. Additionally, reflectometry measurements may be used to detect CD, CD-bias, and other physical parameters related to a substrate processing outcome.

Measurement and/or imaging system 101 may be connected to factory interface 106. Alternatively, measurement and/or imaging system 101 may be connected to transfer chamber (e.g., at a location of one of the illustrated processing chambers). Alternatively, the measurement and/or imaging system 101 may be positioned in an interior of the factory interface 106 or transfer chamber 110. Measurement and/or imaging system 101 may also be a standalone system that is not connected to processing system 100. Measurement and/or imaging system 101 may be mechanically isolated from factory interface 106 and from an external environment to protect measurement and/or imaging system 101 from external vibrations. In some embodiments, measurement and/or imaging system 101 and its contained components may provide analytical measurements (e.g., thickness measurements) that may provide a profile across a surface of a substrate, such as a thickness uniformity profile, a particle count profile, a CD profile, a CD uniformity profile, an optical constant profile, a material property profile, and so on. Measurement and/or imaging system 101 may provide feedback to a user regarding the uniformity profile. Measurement and/or imaging system 101 may be an assembly that has the ability to measure film thicknesses, CD, CD-bias, optical properties, particle count, material properties, surface roughness, etc. across the entire substrate after it is processed in a chamber. Such metrology may be used to monitor process drift, out-of-specification film thickness, out-of-specification CD, CD-bias, etc. for etch, deposition, and/or other processes. The results of the measurement may be used to quickly correct or adjust process parameters of one or more process recipes executed on one or more process chambers to account for any determined process drift. In one embodiment, results of the measurement are used to calibrate an edge ring height to be used for processes in one or more process chambers 114, 116, 118. Although depicted as being connected to factory interface 106, in other embodiments, measurement and/or imaging system 101 may be a standalone reflectometry system or may be positioned at another location in or attached to processing system 100, as described above.

Factory interface robot 126 may place a substrate on a substrate transfer lift (e.g., lift pins) of measurement and/or imaging system 101. In one embodiment, the substrate transfer lift may then lower the substrate onto a substrate support such as a chuck (e.g., a vacuum chuck or electrostatic chuck) of measurement and/or imaging system 101. In other embodiments, the substrate may instead be lowered onto another type of substrate holder, such as a mechanical chuck, a magnetic chuck, or the like. Measurement and/or imaging system 101 may include various covers and a ventilation system to maintain a clean substrate and environment.

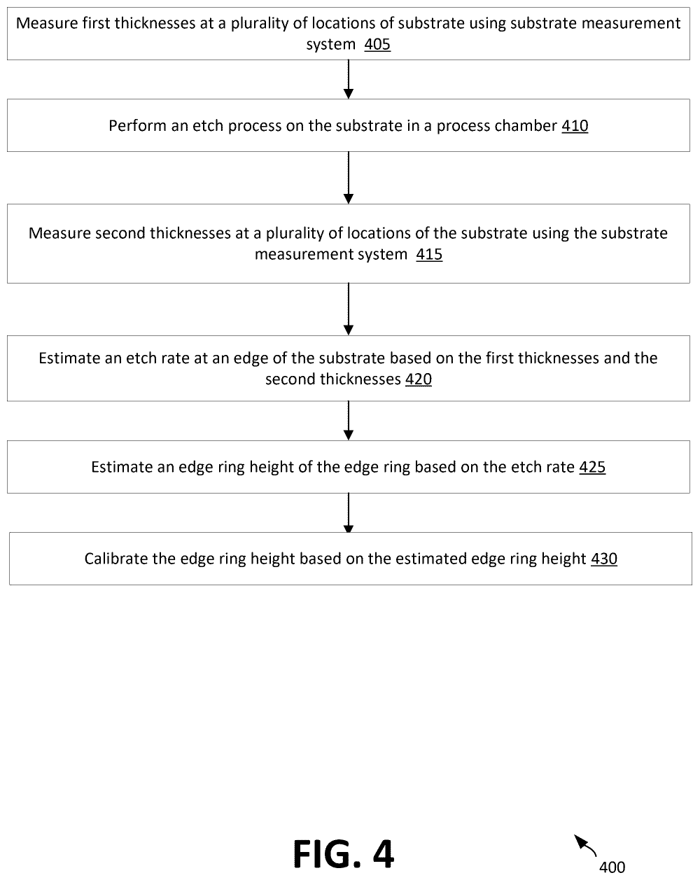

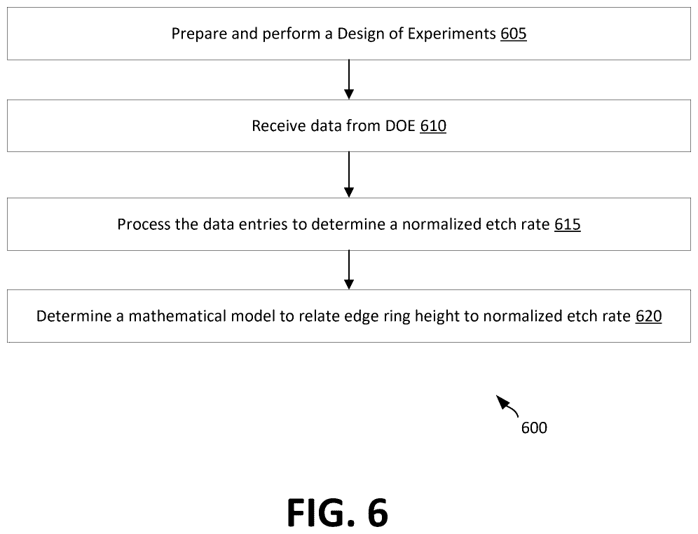

Processing system 100 can also include a system controller 128. System controller 128 can be and/or include a computing device such as a personal computer, a server computer, a programmable logic controller (PLC), a microcontroller, and so on. System controller 128 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. System controller 128 can include a data storage device (e.g., one or more disk drives and/or solid-state drives), a main memory, a static memory, a network interface, and/or other components. System controller 128 can execute instructions to perform any one or more of the methodologies and/or embodiments described herein. For example, system controller 128 may be configured to calibrate an edge ring height based on measurements made on a substrate by imaging system 101. The instructions can be stored on a computer readable storage medium, which can include the main memory, static memory, secondary storage and/or processing device (during execution of the instructions). In embodiments, execution of the instructions by system controller 128 causes system controller to perform the methods of FIGS. 4 and 6. System controller 128 can also be configured to permit entry and display of data, operating commands, and the like by a human operator.

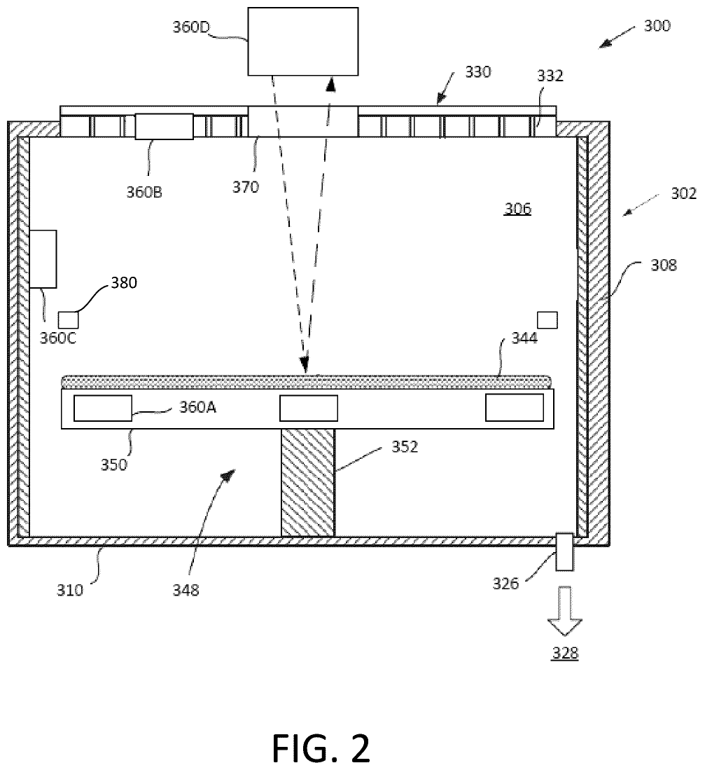

FIG. 2 depicts a cross-sectional schematic side view of a processing chamber 300, according to aspects of the present disclosure. The processing chamber 300 may correspond, for example, to any of process chambers 114, 116, 118 of FIG. 1 in embodiments. The processing chamber 300 may be used for processes in which a corrosive plasma environment is provided. For example, the processing chamber 300 may be a chamber for a plasma etcher or plasma etch reactor, and so forth. In alternative embodiments other processing chambers may be used, which may or may not be exposed to a corrosive plasma environment. Some examples of chamber components include a chemical vapor deposition (CVD) chamber, a physical vapor deposition (PVD) chamber, an atomic layer deposition (ALD) chamber, an ion assisted deposition (IAD) chamber, an etch chamber, and other types of processing chambers.

In one embodiment, the processing chamber 300 includes a chamber body 302 and a showerhead 330 that encloses an interior volume 306. The chamber body 302 generally includes sidewalls 308 and a bottom 310. The showerhead 330 may include a showerhead base and a showerhead gas distribution plate 332. Alternatively, the showerhead 330 may be replaced by a lid and a nozzle in some embodiments, or by multiple pie shaped showerhead compartments and plasma generation units in other embodiments. An exhaust port 326 may be defined in the chamber body 302 and may couple the interior volume 306 to a pump system 328. The pump system 328 may include one or more pumps and throttle valves utilized to evacuate and regulate the pressure of the interior volume 306 of the processing chamber 300.

The showerhead 330 may be supported on the sidewall 308 of the chamber body 302. The showerhead 330 (or lid) may be opened to allow access to the interior volume 306 of the processing chamber 300 and may provide a seal for the processing chamber 300 while closed. A gas panel (not shown) may be coupled to the processing chamber 300 to provide process and/or cleaning gases to the interior volume 306 through the showerhead 330 or lid and nozzle (e.g., through apertures of the showerhead or lid and nozzle).

A substrate support assembly 348 is disposed in the interior volume 306 of the processing chamber 300 below the showerhead 330. The substrate support assembly 348 holds a substrate 344, such as substrate 102 of FIG. 1, during processing. In one embodiment, the substrate support assembly 348 includes a pedestal 352 that supports an electrostatic chuck 350. The electrostatic chuck 350 further includes a thermally conductive base and an electrostatic puck on the thermally conductive base. The thermally conductive base and/or electrostatic puck of the electrostatic chuck 350 may include one or more optional embedded heating elements, embedded thermal isolators and/or conduits to control a lateral temperature profile of the substrate support assembly 348. The electrostatic chuck 350 may include at least one clamping electrode controlled by a chucking power source.

The substrate support assembly 348 include an edge ring 380 that surrounds the substrate 344. A height of the edge ring 380 may affect a plasma sheath at or around an edge of the substrate 344. Depending on a height of the edge ring 380, the plasma sheath may be vertical or may have an acute or obtuse angle relative to a plane of the substrate 344. This may affect both the etch rate at the edge of the substrate 344 and a directionality of etching performed at the edge of the substrate 344. In embodiments, the height of the edge ring 380 is calibrated based on one or more optical measurements made before and after etching.

Processing chamber 300 may include one or more sensors 360 configured to generate data for a substrate 102 and/or an environment surrounding substrate 102 before, after, or during processing of substrate 102. Each sensor 360 may be configured to transmit data to a controller, such as system controller 128. In some embodiments, one or more sensors 360 may be embedded within a component of processing chamber 300 and may be configured to capture data associated with a function of the component. For example, sensors 360A may be embedded within substrate support assembly 348 and/or electrostatic chuck 350. During operation of processing chamber 300, sensors 360A may generate data associated with a temperature of one or more heating elements embedded within the electrostatic chuck 350, a lateral temperature profile of substrate support assembly 348, an amount of power supplied by the chucking power source, etc. In another example, sensors 360B may be embedded within the gas panel and/or showerhead 330. In such example, sensors 360B may be configured to generate data associated with a composition, flow rate and temperature of process and/or cleaning gases provided to the interior volume 306 through showerhead 330. In other or similar embodiments, one or more sensors 360 may be embedded within the interior volume 306 of processing chamber 300 to capture data associated with the environment surrounding substrate 102 during a process. For example, sensors 360C may be embedded on a surface of the chamber body 302 (e.g., sidewall 308). In such example, sensors 360C may be configured to generate data associated with a pressure of interior volume 306, a temperature of interior volume 306, an amount of radiation within interior volume 306, etc.

In some embodiments, one or more sensors 360 outside of processing chamber 300 may be configured to generate data for substrate 102 and/or the environment surrounding substrate 102 before, after, or during processing of substrate 344. For example, sensor 360D may be configured to generate data associated with one or more portions of a surface of substrate 102. A transparent window 370 may be embedded within at least one of showerhead 330 or sidewalls 308. Sensor 360D may be an optical emission device that includes a light source component and a light reflection component. The light source component may be configured to transmit light through transparent window 370 to a portion of substrate 102. Reflected light may be transmitted from the portion of substrate 102, through transparent window 370, and received by light reflection component of sensor 360D. Sensor 360D may generate spectral data associated with the reflected light received by the light reflection component and may transmit the generated spectral data to a controller, such as system controller 128. In some embodiments sensor 360D may be configured to generate spectral data associated with one or more regions of the substrate 344 (e.g., a center portion of substrate 344 and/or an edge of the substrate 344). In other or similar embodiments, sensor 360D may be configured to generate spectral data associated with another portion of substrate 102 (e.g., an outer diameter of substrate 102). The spectral data may be used to determine an etch rate at an edge of the substrate, and the etch rate may be used to determine a height of the edge ring 380. The edge ring height may then be adjusted to a target edge ring height that achieves a target etch rate at the substrate edge and/or a target feature tilt at the substrate edge in embodiments.

In some embodiments, process chamber 300 does not include sensor 360D, and instead a separate imaging system (e.g., such as imaging system 101) that is external to the process chamber 300 is used to measure substrate thickness (e.g., of a film on the substrate) at one or more locations on the substrate before and after processing of the substrate. Such measurements may be used to determine an etch rate at an edge of the substrate, and the etch rate may be used to determine a height of the edge ring 380. The edge ring height may then be adjusted to a target edge ring height that achieves a target etch rate at the substrate edge and/or a target feature tilt at the substrate edge in embodiments.

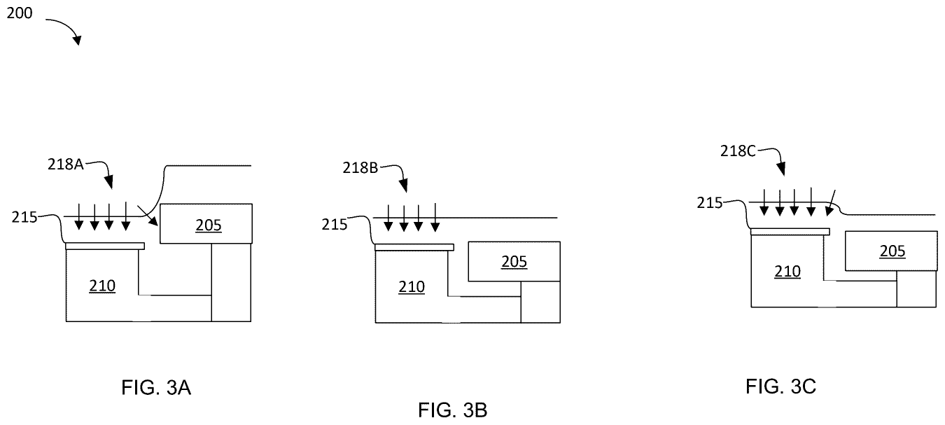

FIGS. 3A-3C illustrate the different edge ring heights and plasma sheath shapes that may occur when a wafer is processed according to an embodiment. In FIG. 3A, a high edge ring height is shown in an embodiment of the substrate processing system 200. The edge ring 205 is illustrated to be above the wafer 215, which is on the substrate holder or electric static chuck 210. When the edge ring 205 is higher than the wafer 215 as is shown, the plasma sheath 218A may have a bend in the plasma sheath's shape or around an interface between the substrate 215 and the edge ring 205. For example, the plasma may be directed away from the substrate center at the substrate edge when a high edge ring height is used. This shape may prevent the wafer 215 from being evenly etched near the extreme edge during a plasma etch process as described herein. With a higher edge ring height, the edge etch rate may be slower when compared to the etch rate of other locations of the wafer. In some embodiments, the high edge ring height may cause a feature tilt at the substrate edge in a direction corresponding to the illustrated vector lines of the plasma sheath 218A. In FIG. 3B, a flush edge ring height is shown in an embodiment. The edge ring 205 may be approximately coplanar with the substrate 215, which may cause the plasma sheath 218B to be similar at the edge ring 205 as on the substrate 215 and may cause the etch rate at the substrate edge to be about equivalent to an etch rate at a center of the substrate 215 in some embodiments. In FIG. 3C, the edge ring 205 is illustrated to be slightly below the wafer 215 (low edge ring height). When the edge ring 205 is lower than the wafer 215, a plasma sheath 218C having different plasma sheath shape occurs than as shown in FIG. 3A. For example, the plasma may be directed inward towards the substrate center at the substrate edge when a low edge ring height is used. This may cause an etch rate at the substrate edge to be higher than the etch rate at the substrate center in embodiments. The relationship between etch rate, feature tilt and edge ring height may be different for different processes. These relationships may be determined based on performing a DOE that varies edge ring height. Once the relationship between edge ring height and substrate edge etch rate and/or feature tilt is determined, the edge ring height may be controlled and/or calibrated to achieve target etch rate and/or feature tilt at the substrate edge.

FIG. 4 is a flowchart illustrating a method 400 of calibrating the edge ring height according to an embodiment. At block 405, first thicknesses at a plurality of locations of a substrate may be measured using the substrate measurement system as described herein. In some embodiments, the measurements of the first thicknesses may be of a preprocessed substrate. After measuring the substrate, an etch process may be performed in a process chamber at block 410. The etch process may be a plasma etch process and may be performed in a process chamber that includes an edge ring having a set edge ring height in embodiments. After performing the etch process, second thicknesses at a plurality of locations of the substrate are measured using the substrate measurement system in block 415. In block 420, an etch rate may be estimated at an edge of the substrate based on the first thicknesses and the second thicknesses of blocks 405 and 415. The thicknesses may be measured at multiple locations on the substrate, such as one or more locations at or near a center of the substrate and one or more locations at or near an edge of the substrate. It is understood that the multiple locations are not limited to the center or near the center, or at or near the edge, but could be any location on the substrate. The etch rates at different locations may be determined, for example, by inputting the pre-etch, and post-etch thickness measurements at those locations into a trained machine learning model (e.g., such as a neural network, a gaussian regression model, etc.), which may output the etch rate at the one or more locations on the substrate. Alternatively, the etch rates may be determined based on one or more mathematical models or formulas that use the pre-etch thicknesses, the post-etch thicknesses and data on an amount of time that etching was performed on the substrate.

In one embodiment, the etch rate estimation logic uses machine learning to estimate etch rates based on before and after thickness profiles of a substrate. One implementation uses a neural network (e.g., a deep neural network to learn how to map an input of before and after thickness measurements (e.g., before and after an etch process) to etch rates. The result of this training is a trained machine learning model that can estimate etch rates of a given etch process given before and after thickness measurements (e.g., before and after thickness profile maps) of a substrate.

The etch rate at the edge of the wafer may be a normalized etch rate in some embodiments. The normalized etch rate may represent a difference between the etch rate between the substrate edge and the etch rate at the substrate center. The normalized etch rate may be estimated by determining a first etch rate associated with a central location on the substrate based on the first thicknesses and the second thicknesses at the central location and determining a second etch rate associated with the edge of the substrate based on the first thicknesses and the second thicknesses at the edge of the substrate. A ratio between the second etch rate and the first etch rate may then be computed to determine the normalize etch rate. In some embodiments, a first profile map (e.g., thickness profile map) of the substrate may be generated based on the first thicknesses and a second profile map of the substrate may be generated based on the second thicknesses. In some embodiments the first profile map and the second profile map may be used to estimate the etch rate at the edge of the substrate.

In block 425, an edge ring height of the edge ring is estimated based on the edge etch rate. In embodiments, the edge ring height is estimated by inputting the edge etch rate into a function or model (e.g., a mathematical model, a statistical model, or a machine learning model), which outputs an edge ring height correlated to the edge etch rate. In embodiments, the function or model may have been generated or trained based on a DOE. The DOE may have included multiple runs of an etch recipe, each using different edge ring heights. For each run, thicknesses may be measured at various locations on a substrate prior to the etch process, the etch process may be run on the substrate using a particular edge ring height, and thicknesses may be measured at the various locations on the substrate after the etch process. For each of the runs using different edge ring heights, different edge etch rates may have been achieved. This information may be used to solve an equation that relates edge ring height to edge etch rates in embodiments. In some embodiments, the solved equation is a linear equation that provides a linear relationship between edge ring height and edge etch rate.

In embodiments, the edge ring height may be determined by inputting the estimated edge etch rate into the linear equation (or non-linear equation in some embodiments). A target etch rate may be predetermined for an etch process. The target etch rate may be input into the equation to determine an edge ring height that achieves the target edge etch rate. Once the current edge ring height is established, a delta between the current edge ring height and the target edge ring height may be determined, and the edge ring height may be adjusted based on the determined delta. This process may constitute calibrating the edge ring height. Accordingly, after estimating the edge ring height, the edge ring height of the substrate can be calibrated using the estimated edge ring height calculated in block 425 in embodiments. In block 425, calibrating may occur by determining a difference between the estimated edge ring height and a target edge ring height and adjusting the edge ring height of the edge ring based on the determined difference, as described above.

In some embodiments, the substrate may include a wafer having a notch. The method of FIG. 4 may further include determining the first thicknesses and second thicknesses associated with the notch (e.g., measured at regions or locations at or near the notch), and removing the first thicknesses and second thicknesses associated with the notch from the estimate edge ring height. Measurements around the notch may have reduced accuracy, and so in embodiments such measurements are filtered out to improve edge ring height calibration accuracy.

In some embodiments, the method of FIG. 4 may further include determining the etch rate at a plurality of different radiuses of the substrate based on the first thicknesses and the second thicknesses and determining normalized etch rates at the plurality of different radiuses based on dividing the etch rates at the plurality of different radiuses by one or more etch rates associated with a center of the substrate, as described above. In some embodiments, the normalized etch rate may be displayed in a graphical user interface as described herein.

In some embodiments, the edge ring height may be associated with a target tilt of etched features, and calibrating the edge ring height may cause substrates processed by the process chamber to have the target tilt of the etched features. In some embodiments, the targe tilt may vary depending on customer specifications for the substrate.

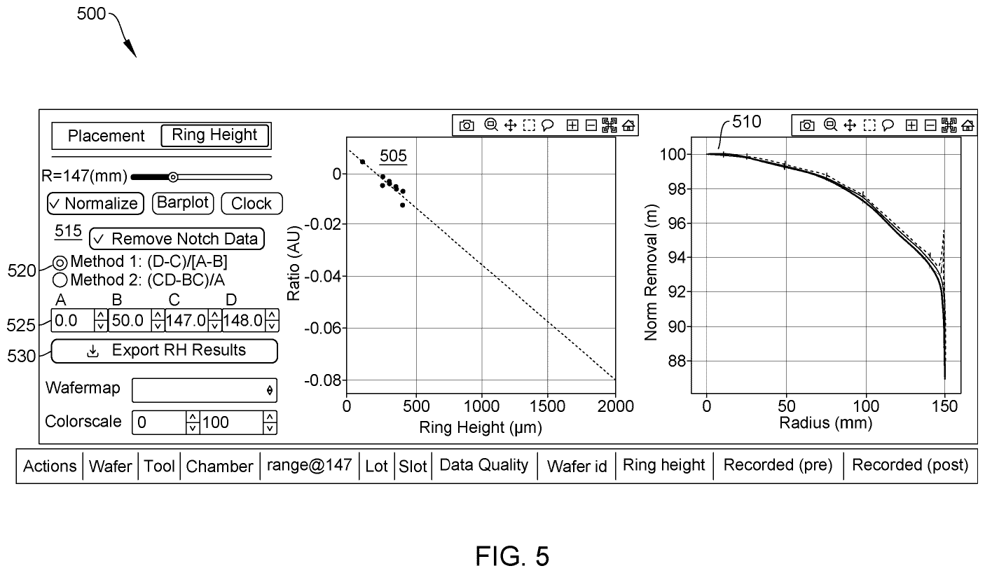

Referring to FIG. 5, a graphic user interface 500 according to an embodiment is illustrated. The graphic user interface 500 displays the results of a DOE performed for an etch process to determine a relationship between edge ring height and edge etch rate. The graphic user interface 500 may display a first graph 505 showing edge ring height along the x-axis and normalized edge etch rate along the y-axis. Each point in first graph 505 may represent a different process run from a DOE. A function relating edge ring height to edge etch rate may be solved by fitting a line to the multiple points in the first graph 505. Once the slope and intercept of a line fit to the multiple points is determined, a linear function may be solved, and may thereafter be used to estimate edge ring height based on measured edge etch rates.

Graphic user interface 500 may additionally include a second graph 510 that relates distance from a wafer center to etch rate. Each line in second graph 510 may correspond to a different run of the DOE (and may correspond to a different edge ring height). An x-axis of the second graph may correspond to a radius from a center of a processed wafer, and a y-axis of the second graph 510 may correspond to a normalized or raw etch rate. The normalized etch rate may be determined by dividing etch rate measurements at each radius by etch rate measurements at the center. Accordingly, the normalized etch rate measurements at the center may always be 1 (e.g., 100%).

In embodiments, a user may adjust the points at which the thickness of the substrate is measured to compute normalized etch rats using the graphical user interface e.g., by updating radius values A, B C and D shown in the graphic user interface 500.

The graphic user interface 500 may further allow a user to adjust the method used to compute normalized etch rates. In one embodiment, a first normalization method uses the equation Er=(D−C)/(A−B) to compute the normalized edge etch rate, where Er is the normalized etch rate, and A, B, C and D are all different radius values and represent the etch rates determined at the respective radius values. In one embodiment, a second normalization method uses the equation Er=(CD−BC)/A to compute the normalized edge etch rate. A user may select which normalization equation to use in some embodiments via the graphic user interface 500 via one or more buttons 520 in embodiments. In some embodiments, a user may select the values for each of radii A, B, C and D to use in computing the normalized edge etch rate via input boxes 525.

In some embodiments, a user may select whether or not to filter out measurements at or around a wafer notch via a remove notch data button 515.

In some embodiments, an export button 530 may be selected to export edge etch rate, edge ring height, and/or edge etch rate to edge ring height correlations, functions and/or models (e.g., to a spreadsheet).

The graphic user interface 500 may also display different data points, not limited to, wafer number, tool number, chamber number, thickness range, lot information, ring height, recorded edge height preprocessing, and/or recorded edge height post processing.

Referring to FIG. 6, a flowchart illustrating a method 600 for determining a mathematical model according to an embodiment is provided. In block 605, a design of experiments (DOE) may be prepared and performed to gather data related to the thickness and edge ring height of a substrate. For the DOE, an etch process may be run multiple times, where each run is performed using a different edge ring height. In block 610, data may be received from the DOE. The data may include a plurality of data entries, each data entry including a pre-etch thickness profile of a substrate, a post-etch thickness profile of the substrate and an edge ring height associated with an etch process performed on the substrate. In block 615, the plurality of data entries may be processed to determine, for each data entry of the plurality of data entries, a normalized etch rate at an edge of the substrate. In block 620, a mathematical model is determined based on the multiple edge etch rates and the known edge ring heights used to achieve each of the edge etch rates. In some embodiments, feature tilt (also referred to as wafer tilt) is measured for each process run of the DOE, and feature tilt may additionally be associated with edge ring height and/or edge etch rate. Accordingly, any of the aforementioned techniques performed to determine an edge ring height that will achieve a target edge etch rate may additionally or alternatively be performed to determine an edge ring height that will achieve a target feature tilt. The mathematical model(s) may relate an edge ring height to the normalized etch rate at the edge of the substrate an/or the feature tilt at the edge of the substrate based on the data from the DOE. The mathematical model may be used to calibrate the edge ring height for one or more process chambers as discussed above.

In some embodiments, the method may further include using the mathematical model determined in block 620 to determine a target edge ring height of an edge ring of a substrate. For example, first thicknesses may be measured at a plurality of locations of a new substrate using a substrate measurement system as described above. An etch process may then be performed on the substrate in a process chamber as described in block 410 of FIG. 4. After the etch process, second thicknesses of the plurality of locations may be measured using the substrate measurement system. A normalized etch rate at the edge of the new substrate may then be estimated based on the first thicknesses and the second thicknesses. An edge ring height of the edge ring may be estimated based on inputting a target etch rate into the mathematical model of FIG. 6. From this model, a target edge ring height of the edge ring may be determined based on inputting a target etch rate into the mathematical model and adjusting the edge ring height of the edge ring based on a difference between the estimated edge ring height and the target edge ring height to calibrate the edge ring height.

In an alternative embodiment, one or more machine learning models may be trained to either perform thickness determination of a substrate, to determine an etch rate, to determine a deposition rate, to determine a treatment rate and/or to determine the edge ring height of a substrate.

One type of machine learning model that may be used to perform some or all of the above tasks is an artificial neural network, such as a deep neural network. Artificial neural networks generally include a feature representation component with a classifier or regression layers that map features to a desired output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g., classification outputs). Deep learning is a class of machine learning algorithms that use a cascade of multiple layers of nonlinear processing units for feature extraction and transformation. Each successive layer uses the output from the previous layer as input. Deep neural networks may learn in a supervised (e.g., classification) and/or unsupervised (e.g., pattern analysis) manner. Deep neural networks include a hierarchy of layers, where the different layers learn different levels of representations that correspond to different levels of abstraction. In deep learning, each level learns to transform its input data into a slightly more abstract and composite representation. Notably, a deep learning process can learn which features to optimally place in which level on its own. The “deep” in “deep learning” refers to the number of layers through which the data is transformed. More precisely, deep learning systems have a substantial credit assignment path (CAP) depth. The CAP is the chain of transformations from input to output. CAPs describe potentially causal connections between input and output. For a feedforward neural network, the depth of the CAPs may be that of the network and may be the number of hidden layers plus one. For recurrent neural networks, in which a signal may propagate through a layer more than once, the CAP depth is potentially unlimited.

Training of a neural network may be achieved in a supervised learning manner, which involves feeding a training dataset consisting of labeled inputs through the network, observing its outputs, defining an error (by measuring the difference between the outputs and the label values), and using techniques such as deep gradient descent and backpropagation to tune the weights of the network across all its layers and nodes such that the error is minimized. In many applications, repeating this process across the many labeled inputs in the training dataset yields a network that can produce correct output when presented with inputs that are different than the ones present in the training dataset.

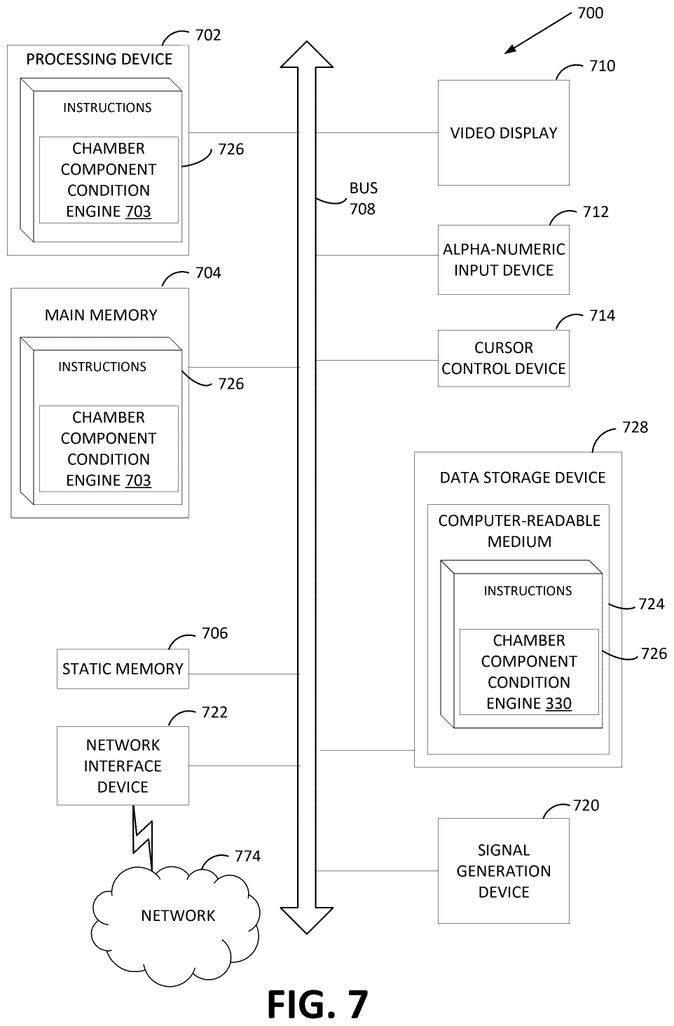

FIG. 7 depicts a block diagram of an example computing device capable of process drift and film thickness determination, operating in accordance with one or more aspects of the disclosure. In various illustrative examples, various components of the computing device 700 may represent various components of a computing device, controller, and/or control panel (e.g., analogous elements described in association with FIGS. 1-2).

Example computing device 700 may be connected to other computer devices in a local area network (LAN), an intranet, an extranet, and/or the Internet. Computing device 900 may operate in the capacity of a server in a client-server network environment. Computing device 900 may be a personal computer (PC), a set-top box (STB), a server, a network router, switch or bridge, or any device capable of executing a set of instructions (sequential or otherwise) that specify actions to be taken by that device. Further, while only a single example computing device is illustrated, the term “computer” shall also be taken to include any collection of computers that individually or jointly execute a set (or multiple sets) of instructions to perform any one or more of the methods discussed herein.

Example computing device 700 may include a processing device 702 (also referred to as a processor or CPU), a main memory 704 (e.g., read-only memory (ROM), flash memory, dynamic random access memory (DRAM) such as synchronous DRAM (SDRAM), etc.), a static memory 706 (e.g., flash memory, static random access memory (SRAM), etc.), and a secondary memory (e.g., a data storage device 718), which may communicate with each other via a bus 708.

Processing device 702 represents one or more general-purpose processing devices such as a microprocessor, central processing unit, or the like. More particularly, processing device 702 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 702 may also be one or more special-purpose processing devices such as an application specific integrated circuit (ASIC), a field programmable gate array (FPGA), a digital signal processor (DSP), network processor, or the like. In accordance with one or more aspects of the disclosure, processing device 702 may be configured to execute instructions implementing methods 400 and 600 illustrated in FIGS. 4 and 6. Processing device 702 may include a chamber condition engine 703. The chamber condition engine 703 can obtain or determine one or more chamber condition metrics for process chamber. Chamber condition metrics may include a selection of values each associated with a combination, feature or pattern identified in the input data.

Example computing device 700 may further comprise a network interface device 708, which may be communicatively coupled to a network 720. Example computing device 700 may further comprise a video display 710 (e.g., a liquid crystal display (LCD), a touch screen, or a cathode ray tube (CRT)), an alphanumeric input device 712 (e.g., a keyboard), a cursor control device 714 (e.g., a mouse), and an acoustic signal generation device 716 (e.g., a speaker).

Data storage device 718 may include a machine-readable storage medium (or, more specifically, a non-transitory machine-readable storage medium) 728 on which is stored one or more sets of executable instructions 722. In accordance with one or more aspects of the disclosure, executable instructions 722 may comprise executable instructions associated with executing methods 400 and 600 illustrated in FIGS. 4 and 5.

Executable instructions 722 may also reside, completely or at least partially, within main memory 704 and/or within processing device 702 during execution thereof by example computing device 700, main memory 704 and processing device 702 also constituting computer-readable storage media. Executable instructions 722 may further be transmitted or received over a network via network interface device 708.

While the computer-readable storage medium 728 may be a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “receiving,” “comparing,” “measuring,” “correcting,” “applying,” “using,” “obtaining,” “replacing,” “performing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Examples of the disclosure also relate to an apparatus for performing the methods described herein. This apparatus may be specially constructed for the target purposes, or it may be a general purpose computer system selectively programmed by a computer program stored in the computer system. Such a computer program may be stored in a computer readable storage medium, such as, but not limited to, any type of disk including optical disks, compact disc read only memory (CD-ROMs), and magnetic-optical disks, read-only memories (ROMs), random access memories (RAMs), erasable programmable read-only memory (EPROMs), electrically erasable programmable read-only memory (EEPROMs), magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general purpose systems may be used with programs in accordance with the teachings herein, or it may prove convenient to construct a more specialized apparatus to perform the method steps. The structure for a variety of these systems will appear as set forth in the description below. In addition, the scope of the disclosure is not limited to any particular programming language. It will be appreciated that a variety of programming languages may be used to implement the teachings of the disclosure.

The preceding description sets forth numerous specific details such as examples of specific systems, components, methods, and so forth, in order to provide a good understanding of several embodiments of the disclosure. It will be apparent to one skilled in the art, however, that at least some embodiments of the disclosure may be practiced without these specific details. In other instances, well-known components or methods are not described in detail or are presented in simple block diagram format in order to avoid unnecessarily obscuring the disclosure. Thus, the specific details set forth are merely exemplary. Particular implementations may vary from these exemplary details and still be contemplated to be within the scope of the disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or. ” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method comprising:
obtaining first thicknesses at a plurality of locations of a substrate;
performing a process on the substrate in a process chamber, wherein the process chamber comprising an edge ring that surrounds the substrate;
measuring, after performing the process, second thicknesses at the plurality of locations of the substrate using a substrate measurement system of the substrate process system;
estimating an etch rate, a deposition rate, or a treatment rate at an edge of the substrate based on the first thicknesses and the second thicknesses;
estimating an edge ring height of the edge ring based on the etch rate, the deposition rate, or the treatment rate; and
calibrating the edge ring height based on the estimated edge ring height comprising:
determining a difference between the estimated edge ring height and a target edge ring height; and
adjusting the edge ring height of the edge ring based on the determined difference.

2. The method of claim 1, further comprising:
generating a first profile map of the substrate based on the first thicknesses; and
generating a second profile map of the substrate based on the second thicknesses, wherein the first profile map and the second profile map are used to estimate the etch rate, deposition rate or treatment rate at the edge of the substrate.

3. The method of claim 1, wherein estimating the etch rate at the edge of the substrate based on the first thicknesses and the second thicknesses comprises:
determining a first etch rate associated with a central location on the substrate based on the first thicknesses and the second thicknesses at the central location;
determining a second etch rate associated with the edge of the substrate based on the first thicknesses and the second thicknesses at the edge of the substrate; and
determining a ratio between the second etch rate and the first etch rate.

4. The method of claim 1, wherein the substrate comprises a wafer having a notch, the method further comprising:
determining the first thicknesses and the second thicknesses associated with the notch; and
removing the first thicknesses and the second thicknesses associated with the notch.

5. The method of claim 1, further comprising:
determining the etch rate at a plurality of different radii of the substrate based on the first thicknesses and the second thicknesses; and
determining normalized etch rates at the plurality of different radii based on dividing the etch rates at the plurality of different radii by one or more etch rates associated with a center of the substrate.

6. The method of claim 5, further comprising:
displaying the normalized etch rates at the plurality of different radiuses in a graphical user interface.

7. The method of claim 1, wherein the target edge ring height is associated with a target tilt of etched features, and wherein calibrating the edge ring height causes substrates processed by the process chamber to have the target tilt of the etched features.

8. The method of claim 1, wherein the process is an etch process.

9. A method comprising:
receiving data comprising a plurality of data entries, each data entry of the plurality of data entries comprising a pre-etch thickness profile of a substrate, a post-etch thickness profile of the substrate, and an edge ring height associated with an etch process performed on the substrate;
processing the plurality of data entries to determine, for each data entry of the plurality of data entries, a normalized etch rate at an edge of the substrate;
determining a mathematical model that relates edge ring height to the normalized etch rate at the edge of the substrate based on the data, wherein the mathematical model is usable to calibrate the edge ring height for one or more process chambers.

10. The method of claim 9, further comprising:
measuring first thicknesses at a plurality of locations of a new substrate using a substrate measurement system of a substrate processing system;
performing the etch process on the substrate in a process chamber;
measuring second thicknesses the plurality of locations of the new substrate using the substrate measurement system of the substrate processing system;
estimating a normalized etch rate at the edge of the new substrate based on the first thicknesses and the second thicknesses;
estimating an edge ring height of the edge ring based on inputting a target etch rate into the mathematical model; and
adjusting the edge ring height of the edge ring based on a difference between the estimated edge ring height and the target edge ring height to calibrate the edge ring height.

11. The method of claim 9, wherein the data is from a design of experiments (DOE).

12. A system comprising:
a process chamber that is configured to perform an etch process;
one or more robots, to move the substrate from the process chamber to a substrate measurement system;
the substrate measurement system configured to measure a thickness of the substrate and to generate a profile map of the substrate; and
a computing device, to:
process data from the profile map using a trained mathematical model, wherein the trained mathematical model outputs an estimated etch rate for the substrate.

13. The system of claim 12, wherein the profile map comprises a thickness profile map of a plurality of locations of a substrate.

14. The system of claim 12, wherein the estimated etch rate comprises an estimation of etching at a target point of the substrate.

15. The system of claim 12, wherein the substrate is a wafer.

16. The system of claim 12, further comprising a display configured to display the output of the trained mathematical model.

17. The system of claim 12, wherein the computing device is also configured to determine if an etch rate should be adjusted based on the outputted estimated etch rate.
